(19) United States
(12) Patent Application Publication
(10) Pub. No.: US 2015/0362564 A1
(43) Pub. Date: Dec. 17, 2015

(54) MAGNETIC SENSING APPARATUS AND MAGNETIC SENSING METHOD THEREOF

(71) Applicant: QST CORPORATION [CN/CN], Shanghai (CN)

(72) Inventors: Hong WAN, Shanghai (CN); Xudong WAN, Shanghai (CN); Ting ZHANG, Shanghai (CN)

(73) Assignee: QST CORPORATION [CN/CN], Shanghai (CN)

(21) Appl. No.: 14/832,810

(22) Filed: Aug. 21, 2015

Related U.S. Application Data
(63) Continuation of application No. PCT/CN2013/088048, filed on Nov. 28, 2013.

(30) Foreign Application Priority Data
Dec. 21, 2012 (CN) 201210563956.3

(51) Int. Cl. G01R 33/02; G01R 33/09

(52) U.S. Cl. CPC G01R 33/0206; G01R 33/09

(57) ABSTRACT

A magnetic sensing apparatus includes a third direction magnetic sensing component that includes a substrate and a pair of coupled magnetic sensing modules. A groove is set in surface of the substrate. The magnetic sensing module includes a magnetic conductive unit, where a main part of the magnetic conductive unit is set in the groove, and a part of it is exposed out the groove and to surface of the substrate, in order to collect magnetic field signal in the third direction and output the magnetic field signal. The magnetic conductive unit includes a magnetic material layer. The magnetic sensing module includes an inducing configured to receive the magnetic field signal in the third direction and measure corresponding magnetic field strength in the third direction by the magnetic field signal. The inducing unit includes a magnetic material layer.

### CROSS-REFERENCE TO RELATED APPLICATIONS

This application is a continuation of International Application No. PCT/CN2013/088048 with an international filing date of Nov. 28, 2013, which is based upon and claims priority to Chinese Patent Application No. 201210563956.3, filed Dec. 21, 2012, the entire contents of which are incorporated herein by reference.

### FIELD

The present disclosure belongs to a technical field of electrical communication, refers to a magnetic sensing apparatus, and more particularly to a magnetic three-axis sensing apparatus in a single chip. The present disclosure also refers to a magnetic sensing method of the magnetic sensing apparatus above.

### BACKGROUND

Magnetic sensor is divided by its principle into hall component, magnetic sensing diode, anisotropic magneto-resistance (AMR) component, tunneling magneto-resistance (TMR) component, giant magneto-resistance (GMR) component, induction coil, and superconductive quantum interference magnetometer.

Electrical compass is one of important application field to magnetic sensor. With rapid development of consumer electronics in recent years, more and more smart phones and panel computers assemble electrical compass beside of navigation system, and it makes users feel very convenience. The magnetic sensor developed from two axis to three axis in recent years. Two-axis magnetic sensor, that is to say plane magnetic sensor, may measure magnetic field strength and direction in a plane illustrated by X and Y-axis.

Operating principle of the magnetic sensor in prior art is shown as below. Anisotropic magneto-resistance material is used in the magnetic sensor to measure the magnetic induction strength in a space. Alloy material with crystal structure adopted here is very sensitive to outside magnetic field, and variation of magnetic field lead to variation of resistance of AMR.

A strong magnetic field is added on an AMR unit to magnetize it in one direction in preparation and application. Then a primary magnetic field is built, and an axis perpendicular to the primary magnetic field is named as sensitive axis of the AMR unit, as illustrated in FIG. 1. Metal wires on the AMR material are canted with 45° to make the measurement result variation linearly, and current flow in these wires and AMR material, as illustrated in FIG. 2. Angle between the primary magnetic field in the AMR material built by the initial strong magnetic field and the current is 45°.

When outside magnetic field Ha exists, direction of the primary magnetic field in AMR unit varies and is not the initial direction, and then angel θ between direction M of magnetic field and current I varies as illustrated in FIG. 3. The variation of θ dues to resistance variation of AMR, as that illustrated in FIG. 4.

The outside magnetic field may be measured by measuring the resistance variation of AMR unit. In real application, a Wheatstone bridge or half Wheatstone bridge in the magnetic sensor is used for measuring the resistance variation of AMR, in order to improve sensitivity of the component, as illustrated in FIG. 5. R1/R2/R3/R4 are ARM resistors with same initial state. When outside magnetic field is detected, the resistances of R1/R2 increase AR, and these of R3/R4 reduce AR. So the output of bridge is zero when outside magnetic field does not exist; and the output of bridge is a small voltage ΔV when outside magnetic field exists.

A sensing part in a plane (two-axis X, and Y) and a sensing part for Z direction are packaged together in system level to realize triaxial sensing for three-axis sensor in prior art. That is to say, the sensing part in the plane and the sensing part for Z direction are set in two independent wafer or chip, and assembled together by packing. It is impossible to realize triaxial sensing in a single wafer/chip in the prior art.

So, a new magnetic sensing apparatus is needed in the prior art, to product a three-axis sensor in a single wafer/chip.

### SUMMARY

In a first aspect, a magnetic sensing apparatus includes a third direction magnetic sensing component. The third direction magnetic sensing component includes a substrate and a pair of coupled magnetic sensing modules, a groove is set in surface of the substrate. The magnetic sensing module includes a magnetic conductive unit, where a main part of the magnetic conductive unit is set in the groove, and a part of it is exposed out the groove and to surface of the substrate, in order to collect magnetic field signal in the third direction and output the magnetic field signal, the magnetic conductive unit comprises a magnetic material layer. The magnetic sensing module includes an inducing unit setting on the surface of the substrate. The inducing unit is configured to receive the magnetic field signal in the third direction and measure corresponding magnetic field strength in the third direction by the magnetic field signal; the inducing unit comprises a magnetic material layer, electrical resistance of the magnetic material in the magnetic material layer is variable with the magnetic field strength and direction. The output magnetic signals in a first direction and/or a second direction for every pairs of coupled magnetic sensing modules may be offset, after the corresponding pair of coupled magnetic sensing modules is settled.

In a second aspect, a magnetic induction method is provided to use the above magnetic sensing apparatus. The method includes: inducing magnetic field in third direction; a magnetic conductive unit collects magnetic signal in the third direction, and outputs the magnetic signal; an inducing unit receives the magnetic signal in the third direction output by the magnetic conductive unit, and measure the magnetic field strength and magnetic field direction corresponding to the third direction by the magnetic signal. Each pair of magnetic sensing modules may directly offset the output magnetic field signal in first and/or second direction of the pair of magnetic sensing modules, after setup of each pair of magnetic sensing modules in the magnetic sensing apparatus is complete.

### DESCRIPTION OF FIGURES

FIG. 1 is schematic diagram for magnetic material of magnetic sensing apparatus in the prior art.

FIG. 2 is schematic diagram for structure of the magnetic material and wire of the magnetic sensing apparatus in the prior art.

FIG. 3 is schematic diagram for angle between magnetic direction and current direction.

FIG. 4 is schematic diagram for θ-R characterization curve of the magnetic material.

FIG. 5 is diagram for a wheatstone bridge.

FIG. 6 is top view diagram for a part of the magnetic sensing apparatus in the present disclosure.

FIG. 7 is section view diagram for the FIG. 1 along A-A direction.

FIG. 8 is schematic diagram for structure of the magnetic sensing apparatus in the present disclosure.

FIG. 9 is top view diagram for a part of the magnetic sensing apparatus in the sixth embodiment.

FIG. 10 is schematic diagram for structure of the magnetic sensing apparatus of the present disclosure in the second embodiment.

FIG. 11 is schematic diagram for structure of the magnetic sensing apparatus of the present disclosure in the third embodiment.

FIG. 12 is schematic diagram for structure of the magnetic sensing apparatus of the present disclosure in the fourth embodiment.

FIG. 13 is schematic diagram for structure of the magnetic sensing apparatus of the present disclosure in the fifth embodiment.

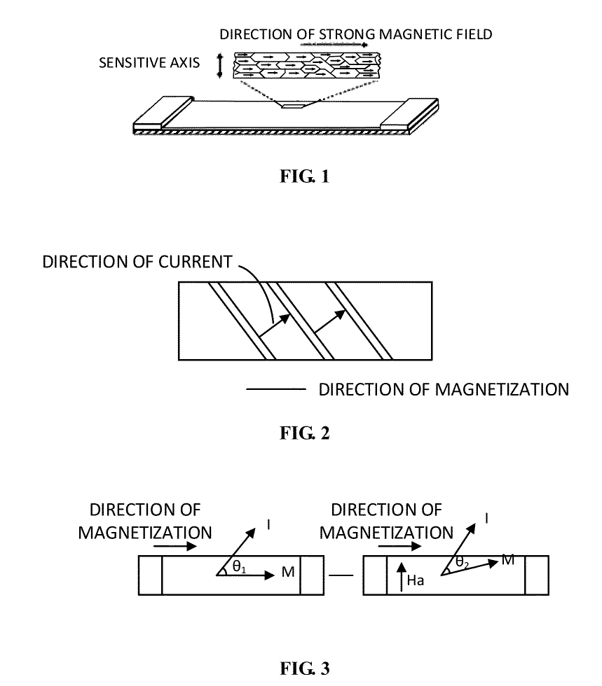

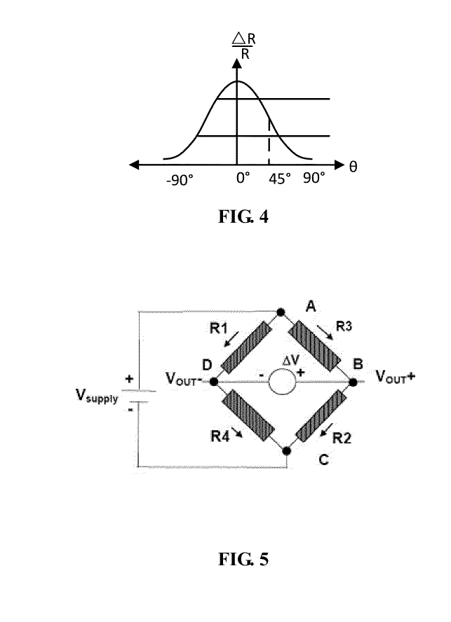

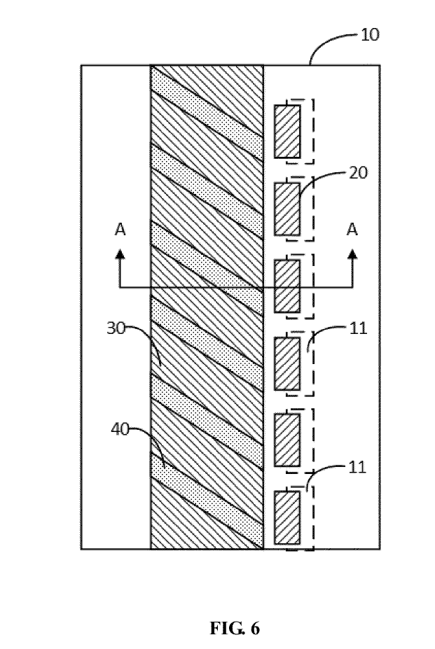

### DETAILED DESCRIPTION

In the present disclosure, in order to solve technical problem, a magnetic sensing apparatus is provided. X-axis, Y-axis, and Z-axis sensing components are set in a single wafer or chip, which has outstanding performance.

Additionally, a magnetic sensing method of the magnetic sensing apparatus above is provided. Magnetic data in X-axis, Y-axis, and Z-axis may be induced according the sensing components in the single wafer or chip.

To solve the technical problem above, a technical proposal is provided in the present disclosure. Embodiments of the present disclosure are illustrated as followed with figures.

### First Embodiment

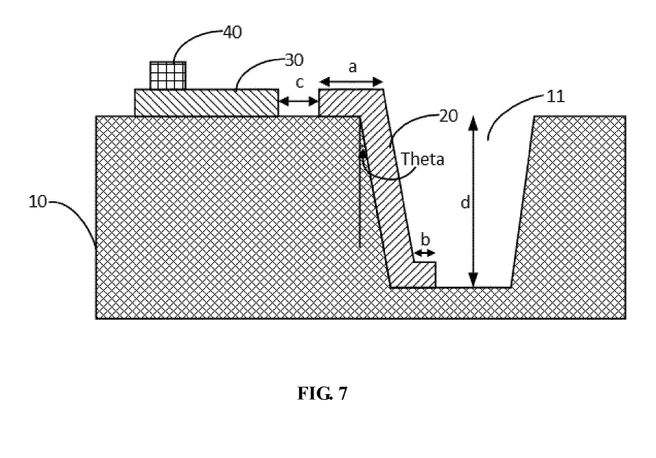

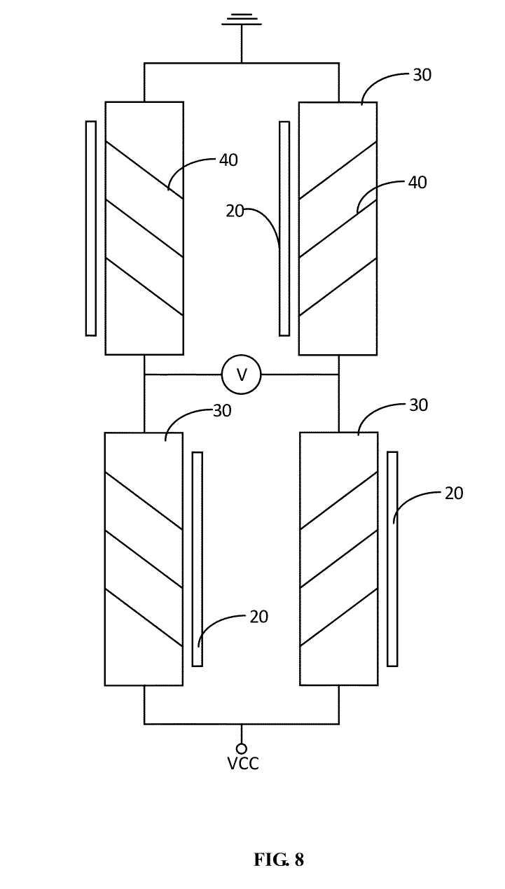

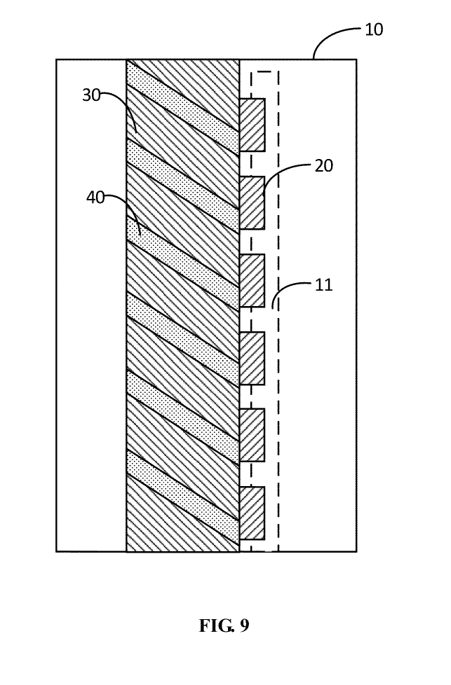

As illustrated in FIG. 6 and FIG. 7, wherein the FIG. 7 is projecting vies of FIG. 6 along A-A direction. The present disclosure discloses a magnetic sensing apparatus, which comprises a Z-axis magnetic sensing component. The Z axis magnetic sensing component comprises: a substrate 10, and at least one pair of coupled magnetic sensing modules; the magnetic sensing modules comprises a magnetic conductive unit 20, and an inducing unit. The substrate 10 may comprise CMOS peripheral circuit. Each pair of magnetic sensing modules may directly offset the output magnetic field signal in X-axis direction and/or Y-axis direction of the pair of magnetic sensing modules, after setup of each pair of magnetic sensing modules in the magnetic sensing apparatus is complete.

There is a dielectric layer on surface of the substrate 10, and grooves 11 in the dielectric layer. One or multiple columns of grooves are set in the substrate. A column of groove comprises multiple sub-grooves 11 in this embodiment.

Main part of the magnetic conductive unit 20 is set in the groove 11, and a part of it is exposed out the groove 11 and to the surface of the substrate, in order to collect magnetic field signal in the Z-axis direction and output the magnetic signal to the inducing unit.

The inducing unit is set on the surface of the substrate, to collect the magnetic field signal in the Z-axis direction output by the magnetic conductive unit 20, and measure corresponding magnetic field strength and direction in the Z-axis direction by the magnetic field signal. The inducing unit comprises magnetic material layer 30, and multiple parallel nodes 40 are set on the magnetic material layer 30. Electrical resistance of the magnetic material in the magnetic material layer 30 relates to direction of the magnetic field. To setup the magnetic conductive unit 20, the inducing unit guide the magnetic field in the Z-axis direction to horizontal direction (X-axis direction and/or Y-axis direction) and then measured.

Meanwhile, the magnetic sensing apparatus also comprises A-axis magnetic sensor, and B-axis magnetic sensor, used for respectively inducing the magnetic signals in X-axis direction and Y-axis direction paralleled to the surface of the substrate (such as strength of the magnetic field and the direction of the magnetic field); The X-axis direction, the Y-axis direction, and the Z-axis direction are perpendicular each other.

The magnetic conductive unit 20 and the magnetic material layer 30 of the inducing unit use same magnetic material, have same number of layers, and are deposited in same process; the magnetic conductive unit 20 and the magnetic material layer 30 of the inducing unit may be AMR, TMR and GMR. Of course, the magnetic conductive unit 20 and the magnetic material layer 30 of the inducing unit may also use different magnetic material, or have different number of layers which are fabricated by multiple times of deposition and lithography.

As illustrated in FIG. 7, angle between the main part of the magnetic conductive unit 20 and the plane that comprising the surface of the substrate is 45°˜90°; and the magnetic material layer 30 of the inducing unit is directly disposed on the surface of the substrate, and paralleled to the surface of the substrate.

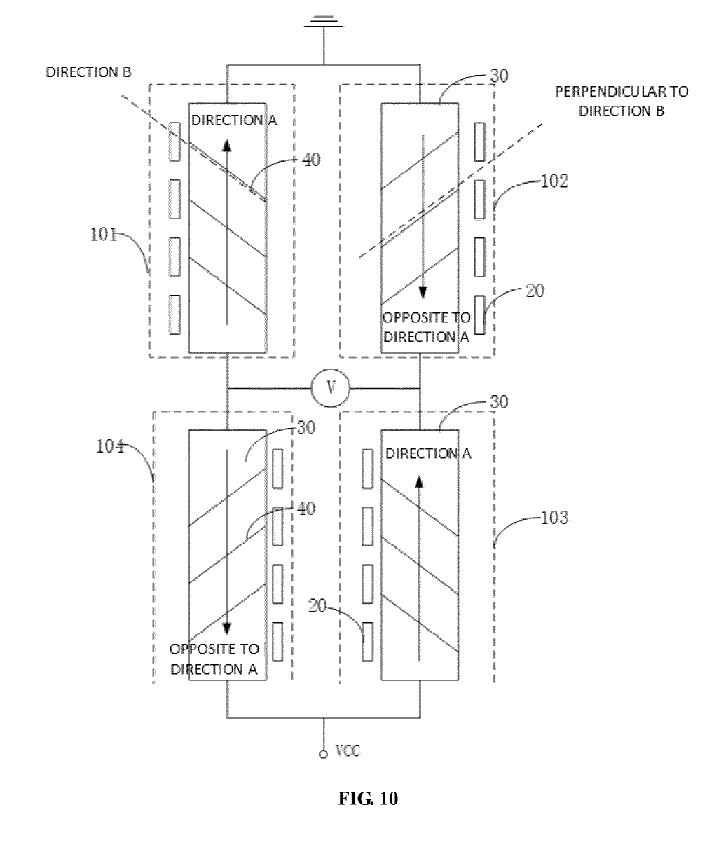

Please refer to FIG. 8, the magnetic conductive unit 20 comprises four magnetic conductive subunits, which are the first magnetic conductive subunit, the second magnetic conductive subunit, the third magnetic conductive subunit, and the fourth magnetic conductive subunit. Refer to FIG. 7, each magnetic conductive subunit comprises multiple magnetic accessories, main part of the magnetic accessory is set in the corresponding groove 11, and a part of it is exposed out of the groove 11; and the exposed part is directly disposed on the magnetic material layer of the corresponding inducing subunit. Optimized distance c is 0-,20 micrometer, and the typical value is 0 micrometer, 0.5 micrometer, 1.0 micrometer, 1.5 micrometer, 5 micrometer, and 10 micrometer. Meanwhile, as illustrated in FIG. 7, range of a is 0-2 micrometer (such as 0.5 micrometer, and 1 micrometer); range of b is 0-1 micrometer (such as 0 micrometer, 0.1 micrometer, and 0.2 micrometer); range of d is 0.5-10 micrometer (such as 3 micrometer, and 6 micrometer); range of angle Theta is 0-45° (such as 5°).

The inducing unit comprises four inducing subunits, which are the first inducing subunit, the second inducing subunit, the third inducing subunit, and the fourth inducing subunit. Each inducing subunit comprises magnetic material layer 30, electrical resistance of the magnetic material in the magnetic material layer 30 relates to the direction of the magnetic field, electrical resistance of the magnetic material in the magnetic material layer is variable with strength and direction of the magnetic field.

The first magnetic conductive subunit is coupled with the first inducing subunit as the first inducing module of the magnetic sensing component in the Z-axis; the second magnetic conductive subunit is coupled with the second inducing subunit as the second inducing module of the magnetic sensing component in the Z-axis; the third magnetic conductive subunit is coupled with the third inducing subunit as the third inducing module of the magnetic sensing component in the Z-axis; the fourth magnetic conductive subunit is coupled with the fourth inducing subunit as the fourth inducing module of the magnetic sensing component in the Z-axis.

A Wheatstone bridge is used in the magnetic sensing apparatus as illustrated in FIG. 8, to measure the magnetic field more sensitive. In the field of application, the magnetic field may also be measured by only one magnetic conductive subunit and one inducing substrate, which are omitted here.

It need to be point out that, three factors of a pair of magnetic sensing modules need to be set, to offset the output magnetic field signal directly in X-axis direction and/or Y-axis direction of the pair of magnetic sensing modules,

each pair of two coupled magnetic sensing modules includes three factors

(1) the relative locations of the groove and the inducing unit; the groove set in one side of the corresponding inducing unit, or other side; the magnetic conductive unit is at left of the inducing unit, to guide the magnetic field in the third direction to one direction in the surface of the substrate, and the magnetic conductive unit is at right of the inducing unit, to guide the magnetic field in the third direction to other direction in the surface of the substrate;

(2) the inducing unit gets an initial magnetization direction by outer exciting magnetic field; and the initial magnetization directions of the two coupled magnetic sensing modules are set as same or opposite; and

(3) direction of current in the magnetic sensing module; the directions of current in the two coupled magnetic sensing modules are set as same or orthographic.

For each of the two coupled magnetic sensing modules, the first factors in the three factors are set as opposite, and the other two are set as same; or all the factors are set as opposite. Of course, there are many deformation in the present disclosure, and this embodiment and embodiments below only disclose several typical schemes of them.

Preferably, each pair of the two coupled magnetic sensing modules above is paralleled, that is to say initial magnetization directions of the magnetic material layer in the inducing unit of the two magnetic sensing module are same or opposite, and directions of the grooves in the two magnetic sensing modules are parallel or overlap. The two magnetic sensing modules should be rolled to paralleled before comparing if the two magnetic sensing modules are not paralleled, and then to compare.

Furthermore, each magnetic sensing modules above is paralleled, and the first factors are set as opposite and the other two factors are set as same for the three factors of the two connected magnetic sensing modules; or all the factors are set as opposite.

In one embodiment of the present disclosure, the apparatus further comprises X-axis Y-axis magnetic sensing component, to induce the magnetic signal in the X-axis and/or Y-axis, and then measure the corresponding magnetic field strength and direction in the X-axis and/or Y-axis direction by it. The X-axis Y-axis magnetic sensing component is not the inducing unit for the Z-axis magnetic sensing component; the inducing unit for the Z-axis magnetic sensing component is for inducing the direction of Z-axis, and the inducing unit for the X-axis Y-axis magnetic sensing component is for inducing the direction of X-axis and/or Y-axis.

The X-axis or Y-axis magnetic sensing component comprises four inducing subunits, which are the fifth inducing subunit, the sixth inducing subunit, the seventh inducing subunit, and the eighth inducing subunit; each of the inducing subunit above comprises a magnetic material layer, on which multiple paralleled electrical nodes are set; and angle between direction of setting the electrical node and direction of magnetization in the magnetic material layer is 10°˜80°, and 45° is optimized. Similarly, the X-axis Y-axis magnetic sensing component may comprise only one inducing unit without Wheatstone bridge.

Structure of the magnetic sensing apparatus in the present disclosure is introduced above, meanwhile a magnetic induction method is disclosed in the present disclosure. The method comprises step of inducing the Z-axis magnetic field, and specifically comprise: a magnetic conductive unit collects magnetic signal in the perpendicular direction, and outputs the magnetic signal; an inducing unit receives the magnetic signal in the perpendicular direction output by the magnetic conductive unit, and measure the magnetic field strength and magnetic field direction corresponding to the perpendicular direction by the magnetic signal. Each pair of magnetic sensing modules may directly offset the output magnetic field signal in first and/or second direction of the pair of magnetic sensing modules, after setup of each pair of magnetic sensing modules in the magnetic sensing apparatus is complete.

In addition, the method further comprises the magnetic inducing step in X-axis direction and Y-axis direction, which comprises: induce the magnetic signal in the X-axis direction and Y-axis direction, and measure the magnetic field strength and magnetic field direction corresponding to the X-axis direction and Y-axis direction by the magnetic signal.

Meanwhile, a preparation method for the magnetic sensing apparatus is disclosed in the present disclosure, which comprise the following steps:

[Step S1] provide a substrate, which may include CMOS peripheral circuit;

[Step S2] there is a dielectric layer on surface of the substrate, to isolate the sensing apparatus and the substrate, set grooves in surface of the substrate through fabrication method;

[Step S3] deposit the magnetic material and protection layer, which are single layer or multiple layer respectively, and then form the inducing unit and the magnetic conductive unit at the same process through fabrication method, so the magnetic conductive unit and the inducing unit are formed by same material deposited in same step. The main part of the magnetic conductive unit is deposited in the groove, and a part of it is exposed out the groove to the surface of the substrate.

Preferably, the magnetic sensing apparatus in the present disclosure also comprises X-axis Y-axis magnetic sensing component; the magnetic material layer needed by the X-axis Y-axis magnetic sensing component is deposited in the same step the inducing unit and the magnetic conductive unit are deposited in the step S3; that is to say the magnetic material layer need by the X-axis, Y-axis and the inducing unit and the magnetic conductive uni-needed by the Z-axis is fabricated in the same step.

Optionally, multiple times of material depositions and fabrication processes are used for forming the inducing unit and the magnetic conductive unit respectively, that is to say different material layers are used for the both.

[Step S4] set the electrical node layer on the inducing unit and the magnetic material layer of the X-axis Y-axis magnetic sensing component, and then finish the fabrication for the whole sensing apparatus through dielectric material depositing, bonding, and so on.

### Second Embodiment

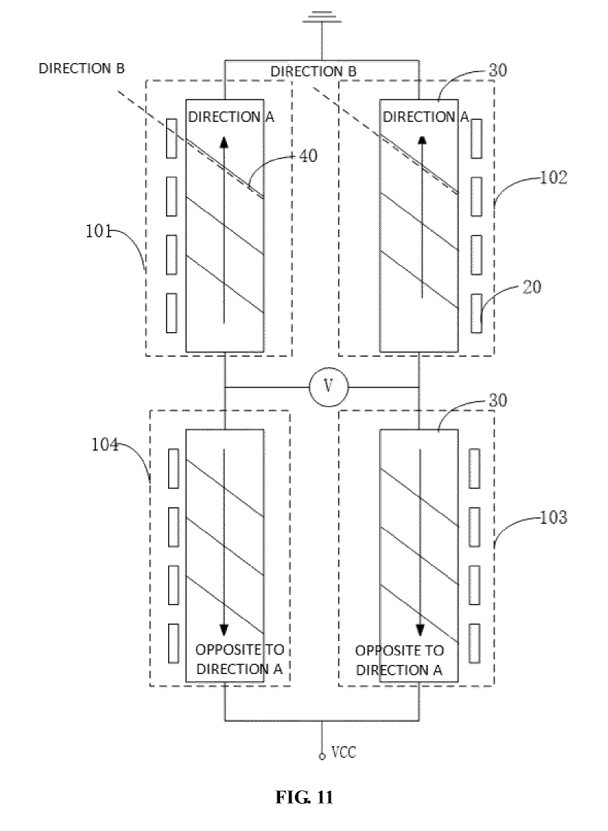

Please refer to FIG. 10, only difference between the present embodiment and the first embodiment is the third direction magnetic sensing component comprises a first magnetic sensing module 101, a second magnetic sensing module 102, a third magnetic sensing module 103, and a fourth magnetic sensing module 104. Each magnetic sensing modules above is paralleled or center points of them are in the same line, that is to say initial magnetization directions of the magnetic material layer in the inducing unit of the two magnetic sensing module are same or opposite, and trends of the grooves in the magnetic sensing modules are paralleled or overlapped.

A first terminal of the first magnetic sensing module 101 and a first terminal of the second magnetic sensing module 102 are grounding, a second terminal of the first magnetic sensing module 101 connects to the a first terminal of the fourth magnetic sensing module 104, a second terminal of the second magnetic sensing module 102 connects to the a first terminal of the third magnetic sensing module 103; a second terminal of the third magnetic sensing module 103 and a second terminal of the fourth magnetic sensing module 104 connect to a power source, and a voltmeter (outputting electrical signal) is connected between a second terminal of the first magnetic sensing module 101 and a second terminal of the second magnetic sensing module 102. The power source, the voltmeter, and the grounding point may be others (such as the grounding point and the power source may be exchanged, and the power source and the voltmeter may be exchanged, and so on), and here are just illustrations.

The grooves coupled to each part of the inducing unit are set in a first side of the coupled part of the inducing unit in the first magnetic sensing module 101; initial magnetization direction of the magnetic material layer in the inducing unit is direction A, and current is direction B;

the grooves coupled to each part of the inducing unit are set in a second side of the coupled part of the inducing unit in the second magnetic sensing module 102; initial magnetization direction of the magnetic material layer in the inducing unit is a direction opposite to the direction A, and current is a direction perpendicular to the direction B;

the grooves coupled to each part of the inducing unit are set in a first side of the coupled part of the inducing unit in the third magnetic sensing module 103; initial magnetization direction of the magnetic material layer in the inducing unit is a direction same to the direction A, and current is a direction paralleled to the direction B;

the grooves coupled to each part of the inducing unit are set in a second side of the coupled part of the inducing unit in the fourth magnetic sensing module 104; initial magnetization direction of the magnetic material layer in the inducing unit is a direction opposite to the direction A, and current is a direction perpendicular to the direction B.

It is disclosed in FIG. 10 that magnetic sensing modules are paralleled each other (such as the first magnetic sensing module 101 and the second magnetic sensing module 102, and the first magnetic sensing module 101 and the fourth magnetic sensing module 104), and for each of the two coupled magnetic sensing modules, the first factor in the three factors is set as opposite, and the other two are set as same; or all the factors are set as opposite.

The magnetic conductive unit and the inducing units comprise a magnetic material layers; material of the magnetic material layer is magneto-resistance material, such as anisotropic magneto-resistance (AMR) material, giant magneto-resistance (GMR) material, or tunneling magneto-resistance (TMR) material; character of them is that electrical resistivity of the material is variable depending on variation of magnetic field.

### Third Embodiment

Please refer to FIG. 11, only difference between the present embodiment and the first embodiment is the third direction magnetic sensing component comprises a first magnetic sensing module 101, a second magnetic sensing module 102, a third magnetic sensing module 103, and a fourth magnetic sensing module 104. Each magnetic sensing modules above is paralleled or center points of them are in the same line, that is to say initial magnetization direction of the magnetic material layer in the inducing unit of the two magnetic sensing module is same or opposite, and trend of the grooves in the magnetic sensing modules are paralleled or overlapped.

A first terminal of the first magnetic sensing module 101 and a first terminal of the second magnetic sensing module 102 are grounding, a second terminal of the first magnetic sensing module 101 connects to the a first terminal of the fourth magnetic sensing module 104, a second terminal of the second magnetic sensing module 102 connects to the a first terminal of the third magnetic sensing module 103; a second terminal of the third magnetic sensing module 103 and a second terminal of the fourth magnetic sensing module 104 connect to a power source, and an electrical signal outputs between a second terminal of the first magnetic sensing module 101 and a second terminal of the second magnetic sensing module 102.

The grooves coupled to each part of the inducing unit are set in a first side of the coupled part of the inducing unit in the first magnetic sensing module 101; initial magnetization direction of the magnetic material layer in the inducing unit is direction A, and current is direction B;

the grooves coupled to each part of the inducing unit are set in a second side of the coupled part of the inducing unit in the second magnetic sensing module 102; initial magnetization direction of the magnetic material layer in the inducing unit is a direction same to the direction A, and current is a direction paralleled to the direction B;

the grooves coupled to each part of the inducing unit are set in a second side of the coupled part of the inducing unit in the third magnetic sensing module 103; initial magnetization direction of the magnetic material layer in the inducing unit is a direction opposite to the direction A, and current is a direction paralleled to the direction B;

the grooves coupled to each part of the inducing unit are set in a first side of the coupled part of the inducing unit in the fourth magnetic sensing module 104; initial magnetization direction of the magnetic material layer in the inducing unit is a direction opposite to the direction A, and current is a direction paralleled to the direction B.

Principle of the magnetic sensing apparatus is anisotropic magneto-resistance (AMR), giant magneto-resistance (GMR), or tunneling magneto-resistance (TMR).

### Fourth Embodiment

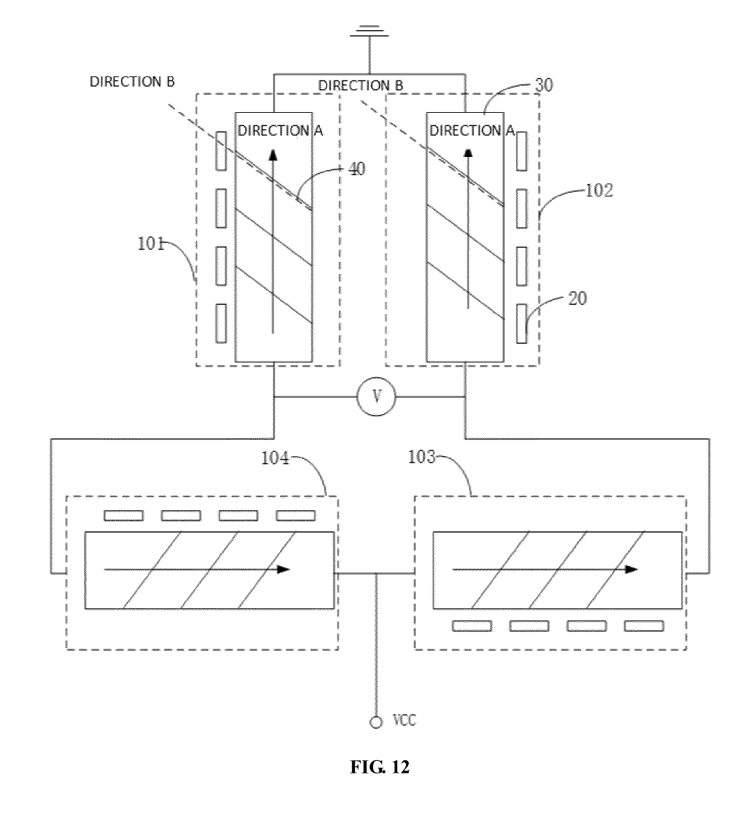

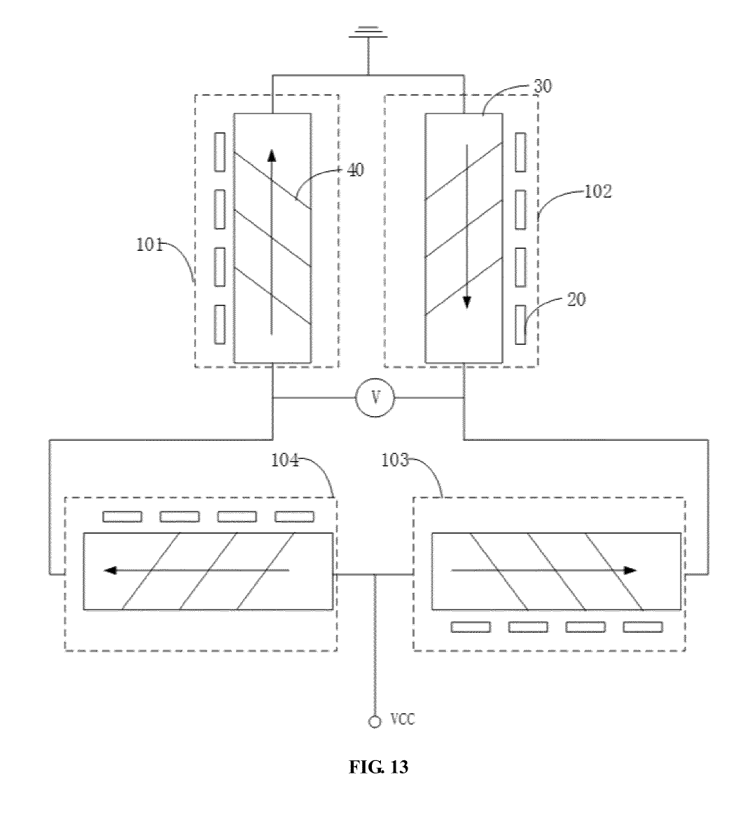

Please refer to FIG. 12, only difference between the present embodiment and the first embodiment is the third direction magnetic sensing component comprises a first magnetic sensing module 101, a second magnetic sensing module 102, a third magnetic sensing module 103, and a fourth magnetic sensing module 104.

Center points of the first magnetic sensing module 101 and the second magnetic sensing module 102 are in the same line, that is to say magnetization directions of the magnetic material layer in the inducing unit of the first magnetic sensing module 101 and the second magnetic sensing module 102 are same or opposite, and trends of the grooves in the magnetic sensing modules are paralleled or overlapped.

The third magnetic sensing module 103 and the fourth magnetic sensing module 104 are respectively perpendicular to the first magnetic sensing module 101, that is to say initial magnetization directions of the magnetic material layer in the inducing unit of the third magnetic sensing module 103 and the fourth magnetic sensing module 104 are respectively perpendicular to the first magnetic sensing module 101, and trend of the grooves in the third magnetic sensing module 103 and the fourth magnetic sensing module 104 are respectively perpendicular to trend of the corresponding grooves in the first magnetic sensing module 101.

A first terminal of the first magnetic sensing module 101 and a first terminal of the second magnetic sensing module 102 are grounding, a second terminal of the first magnetic sensing module 101 connects to the a first terminal of the fourth magnetic sensing module 104, a second terminal of the second magnetic sensing module 102 connects to the a first terminal of the third magnetic sensing module 103; a second terminal of the third magnetic sensing module 103 and a second terminal of the fourth magnetic sensing module 104 connect to a power source, and an electrical signal outputs between a second terminal of the first magnetic sensing module 101 and a second terminal of the second magnetic sensing module 102.

For the coupled first magnetic sensing module 101 and the second magnetic sensing module 102, the relative locations of the groove and the inducing units for them are set as opposite, and the initial magnetization directions and the current directions are set as same in the three factors.

For the coupled third magnetic sensing module 103 and the fourth magnetic sensing module 104, the relative locations of the groove and the inducing units for them are set as opposite, and the initial magnetization directions and current directions are set as same in the three factors.

### Fifth Embodiment

Please refer to FIG. 13, difference between the present embodiment and the fourth embodiment is that, all the three factors for the coupled first magnetic sensing module 101 and the second magnetic sensing module 102 are set as opposite.

All the three factors for the coupled third magnetic sensing module 103 and the second magnetic sensing module 102 are set as opposite.

### Sixth Embodiment

Difference between the present embodiment and the first embodiment is a groove is shared by multiple of magnetic conductive structures in the present embodiment; please refer to FIG. 9, the grooves 11 on the substrate 10 may be set as one column or multiple of columns, and a column of grooves 11 may be set as a narrow groove, used for multiple of magnetic component. Otherwise, the magnetic conductive unit is connected to the sensing unit in this structure, that is to say the distance is 0 micrometer.

### Seventh Embodiment

In the present embodiment, the magnetic sensing apparatus in the present disclosure also comprises CMOS chip, and the substrate mentioned in the first embodiment is set on the CMOS chip. It is to say the magnetic sensing apparatus have functions of the CMOS chip in prior art, That is to say functions of the CMOS chip and the sensing apparatus are integrated into a single chip that have high integration.

### Eighth Embodiment

In the present embodiment, the magnetic material layer needed by the magnetic conductive unit of the magnetic sensing apparatus, inducing unit, and X axis Y axis magnetic sensing component comprises magnetic sensitive material, such as NiFe alloy, and may also comprise buffer layer, such as TaN, and so on. Wherein, the magnetic sensitive material layer and the buffer layer may be multiple layers material.

The magnetic sensitive material comprises anisotropic magneto-resistance material, giant magneto-resistance material, or tunneling magneto-resistance material; it may be multiple layer or single layer; and thickness and number of layers of the multiple layer material may be adjusted by needed.

Additionally or alternatively, multiple magnetic conductive structures may be coupled to one group of magnetic conductive unit, to make the measurement more sensitive.

### Ninth Embodiment

In the present embodiment, three dimensions that the magnetic sensing apparatus may induce are not the first direction, the second direction, and the perpendicular direction of X-axis, Y-axis and Z-axis, and the first direction, the second direction, and the perpendicular direction which are perpendicular for any two should meet the requirements.

In conclusion, the magnetic sensing apparatus and magnetic induction method thereof are provided in the present disclosure, which may set the sensing devices for X-axis, Y-axis, and Z-axis in one wafer or chip, to have good manufacturability, good performance and obvious competitive price. Each pair of magnetic sensing modules may independently measure the magnetic field signal in X-axis direction, Y-axis direction, and Z-axis direction in the present disclosure, after setup of each pair of coupled magnetic sensing modules is complete.

Alternatively or additionally, the third direction magnetic sensing component is a perpendicular direction magnetic sensing component; the magnetic conductive unit is used for collecting the magnetic field signal in the perpendicular direction and output the magnetic signal; the inducing unit is a magnetic sensor inducing magnetic field paralleled to the surface of the substrate, sets on the surface of the substrate, used for receiving the magnetic field signal in the perpendicular direction output by the magnetic conductive unit, and measuring corresponding magnetic field strength in the perpendicular direction by the magnetic field signal; and the magnetic sensing apparatus further comprises a first magnetic sensor, and a second magnetic sensor, in order to induce magnetic field in the first direction, and the second direction respectively. The first direction and the second direction are perpendicular.

Alternatively or additionally, the magnetic sensing apparatus further comprises a first magnetic sensor, and a second magnetic sensor, in order to induce magnetic field in the first direction, and the second direction respectively. The first direction, the second direction, and the third direction are perpendicular each other.

Alternatively or additionally, each pair of coupled magnetic sensing modules includes three factors

(1) the relative locations of the groove and the inducing unit; the groove set in one side of the corresponding inducing unit, or other side; the magnetic conductive unit is at left of the inducing unit, to guide the magnetic field in the third direction to one direction in the surface of the substrate, and the magnetic conductive unit is at right of the inducing unit, to guide the magnetic field in the third direction to other direction in the surface of the substrate;

(2) the inducing unit gets an initial magnetization direction by outer exciting magnetic field; and the initial magnetization directions of the two magnetic sensing modules are set as same or opposite; and

(3) direction of current in the magnetic sensing module; the directions of current in the two magnetic sensing modules are set as same or orthographic.

For each of the two coupled magnetic sensing modules, the first factors in the three factors are set as opposite, and the other two are set as same; or all the factors are set as opposite.

Comparison of the two magnetic sensing modules above is based on the two magnetic sensing modules are paralleled; so called paralleled is that the magnetic material layers of the inducing units in the two magnetic sensing modules above have same or opposite magnetization direction, and direction of the grooves in the two magnetic sensing modules are parallel or overlap;

Alternatively or additionally, each pair of the two coupled magnetic sensing modules above is paralleled, that is to say initial magnetization directions of the magnetic material layer in the inducing unit of the two magnetic sensing module are same or opposite.

Alternatively or additionally, each magnetic sensing modules above is paralleled, and the first factors are set as opposite and the other two factors are set as same for the three factors of the two connected magnetic sensing modules; or all the factors are set as opposite.

Alternatively or additionally, the third direction magnetic sensing component comprises a first magnetic sensing module, a second magnetic sensing module, a third magnetic sensing module, and a fourth magnetic sensing module;

each magnetic sensing modules above is paralleled, that is to say initial magnetization directions of the magnetic material layer in the sensing units of the two magnetic sensing module are same or opposite, and trends of the grooves in the magnetic sensing modules are paralleled or overlapped;

a first terminal of the first magnetic sensing module and a second terminal of the first magnetic sensing module are grounding, a second terminal of the first magnetic sensing module connects to the a first terminal of the fourth magnetic sensing module, a second terminal of the second magnetic sensing module connects to the a first terminal of the third magnetic sensing module; a second terminal of the third magnetic sensing module and a second terminal of the fourth magnetic sensing module connect to a power source, and an electrical signal is output between a second terminal of the first magnetic sensing module and a second terminal of the second magnetic sensing module;

the grooves coupled to each part of the inducing unit are set in a first side of the coupled part of the inducing unit in the first magnetic sensing module; initial magnetization direction of the magnetic material layer in the inducing unit is direction A, and current is direction B;

the grooves coupled to each part of the inducing unit are set in a second side of the coupled part of the inducing unit in the second magnetic sensing module; initial magnetization direction of the magnetic material layer in the inducing unit is a direction opposite to the direction A, and current is a direction perpendicular to the direction B;

the grooves coupled to each part of the inducing unit are set in a first side of the coupled part of the inducing unit in the third magnetic sensing module; initial magnetization direction of the magnetic material layer in the inducing unit is a direction same to the direction A, and current is a direction paralleled to the direction B;

the grooves coupled to each part of the inducing unit are set in a second side of the coupled part of the inducing unit in the fourth magnetic sensing module; initial magnetization direction of the magnetic material layer in the inducing unit is a direction opposite to the direction A, and current is a direction perpendicular to the direction B.

Alternatively or additionally, the third direction magnetic sensing component may include a first magnetic sensing module, a second magnetic sensing module, a third magnetic sensing module, and a fourth magnetic sensing module. Each magnetic sensing modules above is paralleled, that is to say initial magnetization directions of the magnetic material layer in the inducing unit of the two magnetic sensing module are same or opposite, and trends of the grooves in the magnetic sensing modules are paralleled or overlapped. A first terminal of the first magnetic sensing module and a first terminal of the second magnetic sensing module are grounding, a second terminal of the first magnetic sensing module connects to the a first terminal of the fourth magnetic sensing module, a second terminal of the second magnetic sensing module connects to the a first terminal of the third magnetic sensing module; a second terminal of the third magnetic sensing module and a second terminal of the fourth magnetic sensing module connect to a power source, and an electrical signal is output between a second terminal of the first magnetic sensing module and a second terminal of the second magnetic sensing module.

The grooves coupled to each part of the inducing unit are set in a first side of the coupled part of the inducing unit in the first magnetic sensing module; initial magnetization direction of the magnetic material layer in the inducing unit is direction A, and current is direction B. The grooves coupled to each part of the inducing unit are set in a second side of the coupled part of the inducing unit in the second magnetic sensing module; initial magnetization direction of the magnetic material layer in the inducing unit is a direction same to the direction A, and current is a direction paralleled to the direction B. The grooves coupled to each part of the inducing unit are set in a first side of the coupled part of the inducing unit in the third magnetic sensing module; initial magnetization direction of the magnetic material layer in the inducing unit is a direction same to the direction A, and current is a direction paralleled to the direction B. The grooves coupled to each part of the inducing unit are set in a second side of the coupled part of the inducing unit in the fourth magnetic sensing module; initial magnetization direction of the magnetic material layer in the inducing unit is a direction same to the direction A, and current is a direction paralleled to the direction B.

Alternatively or additionally, the third direction magnetic sensing component comprises a first magnetic sensing module, a second magnetic sensing module, a third magnetic sensing module, and a fourth magnetic sensing module. Center points of the first magnetic sensing module and the second magnetic sensing module are in the same line, that is to say magnetization directions of the magnetic material layer in the inducing unit of the first magnetic sensing module and the second magnetic sensing module are same or opposite, and trends of the grooves in the magnetic sensing modules are paralleled or overlapped.

The third magnetic sensing module and the fourth magnetic sensing module are respectively perpendicular to the first magnetic sensing module and the second magnetic sensing module, that is to say initial magnetization directions of the magnetic material layer in the inducing unit of the third magnetic sensing module and the fourth magnetic sensing module are respectively perpendicular to the first magnetic sensing module and the second magnetic sensing module, and trends of the grooves in the third magnetic sensing module and the fourth magnetic sensing module are respectively perpendicular to trend of the corresponding grooves in the first magnetic sensing module and the second magnetic sensing module.

A first terminal of the first magnetic sensing module and a first terminal of the second magnetic sensing module are grounding, a second terminal of the first magnetic sensing module connects to the a first terminal of the fourth magnetic sensing module, a second terminal of the second magnetic sensing module connects to the a first terminal of the third magnetic sensing module; a second terminal of the third magnetic sensing module and a second terminal of the fourth magnetic sensing module connect to a power source, and an electrical signal is output between a second terminal of the first magnetic sensing module and a second terminal of the second magnetic sensing module. For the coupled first magnetic sensing module and the second magnetic sensing module, the relative location of the groove and the inducing units for them are set as opposite, and the initial magnetization directions and the current directions are set as same in the three factors; or the relative location of the groove and the inducing units for them are set as opposite, the initial magnetization directions set as opposite, and the current directions are perpendicular. For the coupled third magnetic sensing module and the fourth magnetic sensing module, the relative location of the groove and the inducing units for them are set as opposite, and the initial magnetization directions and current directions are set as same in the three factors; or the relative location of the groove and the inducing units for them are set as opposite, the initial magnetization directions set as opposite, and the current directions are perpendicular.

Alternatively or additionally, the third direction magnetic sensing component comprises a peripheral circuit, used for calculating magnetic field strength and magnetic field direction, and outputting; angle between main part of the magnetic conductive unit and surface of the substrate is 45°˜90°; the inducing unit is directly disposed on the surface of the substrate, and paralleled to the surface of the substrate; the first direction is X-axis, the second direction is Y-axis, and the third direction is Z-axis.

Alternatively or additionally, the apparatus further comprises a second magnetic sensing component, used for sensing magnetic signal in the first direction and/or the second direction, and measuring the corresponding magnetic field strength and magnetic field direction in the first direction and/or the second direction by it.

Alternatively or additionally, the second magnetic sensing component comprises four inducing subunits, which are a fifth inducing subunit, a sixth inducing subunit, a seventh inducing subunit, and an eighth inducing subunit. Each inducing subunit above comprises a magnetic material layer, electrical resistance of magnetic material in the magnetic material layer is variable depending on the magnetic field strength and direction; and angle between direction of setting the electrical node and direction of magnetization in the magnetic material layer is 10°˜80°.

Alternatively or additionally, the magnetic conductive unit comprises four magnetic conductive subunits, which are a first magnetic conductive subunit, a second magnetic conductive subunit, a third magnetic conductive subunit, and a fourth magnetic conductive subunit. The inducing unit comprises four inducing subunits, which are a first inducing subunit, a second inducing subunit, a third inducing subunit, and a fourth inducing subunit.

The first magnetic conductive subunit is coupled with the first inducing subunit as the first inducing module of the magnetic sensing component in the third direction. The second magnetic conductive subunit is coupled with the second inducing subunit as the second inducing module of the magnetic sensing component in the third direction. The third magnetic conductive subunit is coupled with the third inducing subunit as the third inducing module of the magnetic sensing component in the third direction. The fourth magnetic conductive subunit is coupled with the fourth inducing subunit as the fourth inducing module of the magnetic sensing component in the third direction.

Each inducing subunit above comprises a magnetic material layer, electrical resistance of magnetic material in the magnetic material layer is variable depending on the magnetic field strength and direction, multiple paralleled electrical nodes are set on the magnetic material layer; angle between direction of setting the electrical node and direction of magnetization in the magnetic material layer is 10°˜80°. The magnetic conductive unit and the inducing unit comprise magnetic material layers respectively; material of the magnetic material layer is magneto-resistance material, anisotropic magneto-resistance (AMR) material, giant magneto-resistance (GMR) material, or tunneling magneto-resistance (TMR) material; character of them is that electrical resistivity of the material is variable depending on variation of magnetic field.

Principle of the magnetic sensing apparatus is anisotropic magneto-resistance (AMR), giant magneto-resistance (GMR), or tunneling magneto-resistance (TMR).

One or multiple columns of grooves are set in the substrate, and a column of grooves is formed by a long and narrow groove, or a column of grooves comprises multiple sub-grooves.

Each magnetic conductive subunit may include multiple magnetic accessories, main part of the magnetic accessory is set in the corresponding groove, and a part of it is exposed out of the groove; and the exposed part is directly disposed on the magnetic material layer of the corresponding inducing subunit. Each magnetic accessory may have the exposed part out of the groove, and distance between the exposed part and the magnetic material layer of the corresponding inducing subunit is 0-20 micrometers.

Alternatively or additionally, the magnetic conductive unit and the magnetic material layer of the inducing unit are formed by same magnetic material, and have same number of layers deposited in same step; the magnetic conductive unit and the magnetic material layer of the inducing unit are formed by different magnetic material deposited in different steps.

Alternatively or additionally, the method further comprises the inducing step in the first direction and the second direction. Induce the magnetic signal in the first direction and the second direction, and measure the magnetic field strength and magnetic field direction corresponding to the first direction and the second direction by them.

The advantage of the present disclosure is that, an inducing unit with X, Y, and Z-axis direction in a single wafer/chip is provided in the magnetic sensing apparatus and the magnetic induction method provided in the present disclosure, and the peripheral ASIC circuit is integrated optionally on the single chip using fully compatible process with standard CMOS process; and it is easy to product, has outstanding performance, and has competitive price. In the present disclosure, the magnetic signals in X-axis, Y-axis, and Z-axis may be measured independently, after setup of each two coupled magnetic sensing modules is complete.

The description and application of the present disclosure are illustrative, and does not tend to restrict the present disclosure to the embodiments above. Any transformation and change are allowed for the embodiments, and to replace any embodiment and any components is well known for common skilled persons in the technical field. The skilled persons in the technical field should be clear that, the present disclosure may be in other forms, structure, layout, scale, and other devices, materials and components, within the spirit or essential characteristics of the present disclosure. Any transformation and change are allowed for the embodiments disclosed here, within the scope and spirit of the present disclosure.

What is claimed is:

1. A magnetic sensing apparatus, comprising a third direction magnetic sensing component, the third direction magnetic sensing component comprises a substrate and a pair of coupled magnetic sensing modules, a groove is set in surface of the substrate; and
the magnetic sensing module comprises:
a magnetic conductive unit, main part of the magnetic conductive unit is set in the groove, and a part of it is exposed out the groove and to surface of the substrate, in order to collect magnetic field signal in the third direction and output the magnetic field signal; and
an inducing unit setting on the surface of the substrate, to receive the magnetic field signal in the third direction and measure corresponding magnetic field strength in the third direction by the magnetic field signal; the inducing unit comprises a magnetic material layer, electrical resistance of the magnetic material in the magnetic material layer is variable with the magnetic field strength and direction, and
wherein output magnetic signals in a first direction and/or a second direction for every pairs of coupled magnetic sensing modules are offset after the pair of coupled magnetic sensing modules is settled.

2. The magnetic sensing apparatus of claim 1, wherein:
the third direction magnetic sensing component comprises a perpendicular direction magnetic sensing component;
the magnetic conductive unit is configured to collect the magnetic field signal in a perpendicular direction and outputting the magnetic field signal;
the inducing unit comprises a magnetic sensor inducing magnetic field paralleled to the surface of the substrate, sets on the surface of the substrate, configured to receive the magnetic field signal in the perpendicular direction from the magnetic conductive unit, and measuring corresponding magnetic field strength in the perpendicular direction by the magnetic field signal; and
the magnetic sensing apparatus further comprises a first magnetic sensor and a second magnetic sensor configured to respectively induce magnetic field in the first direction, and the second direction; and the first direction and the second direction are perpendicular to each other.

3. The magnetic sensing apparatus of claim 1, wherein:
the magnetic sensing apparatus further comprises a first magnetic sensor and a second magnetic sensor configured to respectively induce magnetic field in the first direction, and the second direction; and
the first direction, the second direction, and the third direction are perpendicular each other.

4. The magnetic sensing apparatus of claim 1, wherein each pair of two coupled magnetic sensing modules comprises three factors:
(1) for relative locations of the groove and the inducing unit, the groove sets in one side of the corresponding inducing unit, or other side; the magnetic conductive unit is at left of the inducing unit, to guide the magnetic field in the third direction to one direction in the surface of the substrate, and the magnetic conductive unit is at right of the inducing unit, to guide the magnetic field in the third direction to other direction in the surface of the substrate;
(2) the inducing unit gets an initial magnetization direction by outer exciting magnetic field; and the initial magnetization directions of the two coupled magnetic sensing modules are set as same or opposite; and
(3) for direction of current in the magnetic sensing module, the directions of current in the two coupled magnetic sensing modules are set as same or orthographic;
for each of the two coupled magnetic sensing modules, factors (1) in the three factors are set as opposite, and factors (2) and (3) are set as same; or all three factors are set as opposite;
comparison of the two coupled magnetic sensing modules above is based on the two coupled magnetic sensing modules are paralleled.

5. The magnetic sensing apparatus of claim 4, wherein:
each pair of the two coupled magnetic sensing modules above is paralleled so that initial magnetization directions of the magnetic material layer in the inducing unit of the two coupled magnetic sensing module are same or opposite.

6. The magnetic sensing apparatus of claim 4, wherein:
each magnetic sensing modules above is paralleled, and factors (1) are set as opposite and the factors (2) and (3) are set as same for all three factors of two connected magnetic sensing modules; or all three factors are set as opposite.

7. The magnetic sensing apparatus of claim 4, wherein:
the third direction magnetic sensing component comprises a first magnetic sensing module, a second magnetic sensing module, a third magnetic sensing module, and a fourth magnetic sensing module;
each magnetic sensing modules above is paralleled so that initial magnetization directions of the magnetic material layer in sensing units of the two coupled magnetic sensing modules are same or opposite, and trend of the grooves in the magnetic sensing modules are paralleled or overlapped;
a first terminal of the first magnetic sensing module and a second terminal of the first magnetic sensing module are grounding, a second terminal of the first magnetic sensing module connects to the a first terminal of the fourth magnetic sensing module, a second terminal of the second magnetic sensing module connects to the a first terminal of the third magnetic sensing module; a second terminal of the third magnetic sensing module and a second terminal of the fourth magnetic sensing module connect to a power source, and an electrical signal is output between a second terminal of the first magnetic sensing module and a second terminal of the second magnetic sensing module;
the grooves coupled to each part of the inducing unit are set in a first side of the coupled part of the inducing unit in the first magnetic sensing module; initial magnetization direction of the magnetic material layer in the inducing unit is direction A, and current is direction B;
the grooves coupled to each part of the inducing unit are set in a second side of the coupled part of the inducing unit in the second magnetic sensing module;
initial magnetization direction of the magnetic material layer in the inducing unit is a direction opposite to the direction A, and current is a direction perpendicular to the direction B;
the grooves coupled to each part of the inducing unit are set in a first side of the coupled part of the inducing unit in the third magnetic sensing module; initial magnetization direction of the magnetic material layer in the inducing unit is a direction same to the direction A, and current is a direction paralleled to the direction B;
the grooves coupled to each part of the inducing unit are set in a second side of the coupled part of the inducing unit in the fourth magnetic sensing module;
initial magnetization direction of the magnetic material layer in the inducing unit is a direction opposite to the direction A, and current is a direction perpendicular to the direction B.

8. The magnetic sensing apparatus of claim 4, wherein:
the third direction magnetic sensing component comprises a first magnetic sensing module, a second magnetic sensing module, a third magnetic sensing module, and a fourth magnetic sensing module;
each magnetic sensing modules above is paralleled so that initial magnetization directions of the magnetic material layer in the inducing unit of the two coupled magnetic sensing modules are same or opposite, and trend of the grooves in the magnetic sensing modules are paralleled or overlapped;
a first terminal of the first magnetic sensing module and a first terminal of the second magnetic sensing module are grounding, a second terminal of the first magnetic sensing module connects to the a first terminal of the fourth magnetic sensing module, a second terminal of the second magnetic sensing module connects to the a first terminal of the third magnetic sensing module; a second terminal of the third magnetic sensing module and a second terminal of the fourth magnetic sensing module connect to a power source, and an electrical signal is output between a second terminal of the first magnetic sensing module and a second terminal of the second magnetic sensing module;
the grooves coupled to each part of the inducing unit are set in a first side of the coupled part of the inducing unit in the first magnetic sensing module; initial magnetization direction of the magnetic material layer in the inducing unit is direction A, and current is direction B;
the grooves coupled to each part of the inducing unit are set in a second side of the coupled part of the inducing unit in the second magnetic sensing module;
initial magnetization direction of the magnetic material layer in the inducing unit is a direction same to the direction A, and current is a direction paralleled to the direction B;
the grooves coupled to each part of the inducing unit are set in a first side of the coupled part of the inducing unit in the third magnetic sensing module; initial magnetization direction of the magnetic material layer in the inducing unit is a direction same to the direction A, and current is a direction paralleled to the direction B;
the grooves coupled to each part of the inducing unit are set in a second side of the coupled part of the inducing unit in the fourth magnetic sensing module;
initial magnetization direction of the magnetic material layer in the inducing unit is a direction same to the direction A, and current is a direction paralleled to the direction B.

9. The magnetic sensing apparatus of claim 4, wherein:
the third direction magnetic sensing component comprises a first magnetic sensing module, a second magnetic sensing module, a third magnetic sensing module, and a fourth magnetic sensing module;
center points of the first magnetic sensing module and the second magnetic sensing module are in the same line so that magnetization directions of the magnetic material layer in the inducing unit of the first magnetic sensing module and the second magnetic sensing module are same or opposite, and trend of the grooves in the magnetic sensing modules are paralleled or overlapped;
the third magnetic sensing module and the fourth magnetic sensing module are respectively perpendicular to the first magnetic sensing module and the second magnetic sensing module so that initial magnetization directions of the magnetic material layer in the inducing unit of the third magnetic sensing module and the fourth magnetic sensing module are respectively perpendicular to the first magnetic sensing module and the second magnetic sensing module, and trend of the grooves in the third magnetic sensing module and the fourth magnetic sensing module are respectively perpendicular to trend of corresponding grooves in the first magnetic sensing module and the second magnetic sensing module;
a first terminal of the first magnetic sensing module and a first terminal of the second magnetic sensing module are grounding, a second terminal of the first magnetic sensing module connects to the a first terminal of the fourth magnetic sensing module, a second terminal of the second magnetic sensing module connects to the a first terminal of the third magnetic sensing module; a second terminal of the third magnetic sensing module and a second terminal of the fourth magnetic sensing module connect to a power source, and an electrical signal is output between a second terminal of the first magnetic sensing module and a second terminal of the second magnetic sensing module;
for the coupled first magnetic sensing module and the second magnetic sensing module, the relative location of the groove and the inducing units for them are set as opposite, and the initial magnetization directions and the current directions are set as same in the three factors; or the relative location of the groove and the inducing units for them are set as opposite, the initial magnetization directions set as opposite, and the current directions are perpendicular;
for the coupled third magnetic sensing module and the fourth magnetic sensing module, the relative location of the groove and the inducing units for them are set as opposite, and the initial magnetization directions and current directions are set as same in the three factors; or the relative location of the groove and the inducing units for them are set as opposite, the initial magnetization directions set as opposite, and the current directions are perpendicular.

10. The magnetic sensing apparatus of claim 1, wherein:
the third direction magnetic sensing component comprises a peripheral circuit, used for calculating magnetic field strength and magnetic field direction, and outputting;
angle between main part of the magnetic conductive unit and surface of the substrate is 45°˜90°; the inducing unit is directly disposed on the surface of the substrate, and paralleled to the surface of the substrate;
the first direction is X-axis, the second direction is Y-axis, and the third direction is Z-axis.

11. The magnetic sensing apparatus of claim 1, wherein:
the apparatus further comprises a second magnetic sensing component, used for sensing magnetic signal in the first direction and/or the second direction, and measuring the corresponding magnetic field strength and magnetic field direction in the first direction and/or the second direction by it.

12. The magnetic sensing apparatus of claim 11, wherein:
the second magnetic sensing component comprises four inducing subunits, which are a fifth inducing subunit, a sixth inducing subunit, a seventh inducing subunit, and an eighth inducing subunit;
each inducing subunit above comprises a magnetic material layer, electrical resistance of magnetic material in the magnetic material layer is variable depending on the magnetic field strength and direction.

13. The magnetic sensing apparatus of claim 1, wherein:
the magnetic conductive unit comprises four magnetic conductive subunits, which are a first magnetic conductive subunit, a second magnetic conductive subunit, a third magnetic conductive subunit, and a fourth magnetic conductive subunit;
the inducing unit comprises four inducing subunits, which are a first inducing subunit, a second inducing subunit, a third inducing subunit, and a fourth inducing subunit;
the first magnetic conductive subunit is coupled with the first inducing subunit as the first inducing module of the magnetic sensing component in the third direction;
the second magnetic conductive subunit is coupled with the second inducing subunit as the second inducing module of the magnetic sensing component in the third direction;
the third magnetic conductive subunit is coupled with the third inducing subunit as the third inducing module of the magnetic sensing component in the third direction;
the fourth magnetic conductive subunit is coupled with the fourth inducing subunit as the fourth inducing module of the magnetic sensing component in the third direction;
each inducing subunit above comprises a magnetic material layer, electrical resistance of magnetic material in the magnetic material layer is variable depending on the magnetic field strength and direction;
one or multiple columns of grooves are set in the substrate, and a column of grooves is formed by a long groove, or a column of grooves comprises multiple sub-grooves;
each magnetic conductive subunit comprises multiple magnetic accessories, main part of the magnetic accessory is set in a corresponding groove, and a part of it is exposed out of the groove; and the exposed part is directly disposed on the magnetic material layer of the corresponding inducing subunit;
each magnetic accessory has the exposed part out of the groove, and distance between the exposed part and the magnetic material layer of the corresponding inducing subunit is 0-20 micrometer.

14. The magnetic sensing apparatus of claim 1, wherein:
the magnetic conductive unit and the inducing unit comprise magnetic material layers respectively; and
material of the magnetic material layer is magneto-resistance material, anisotropic magneto-resistance (AMR) material, giant magneto-resistance (GMR) material, or tunneling magneto-resistance (TMR) material; character of them is AMR, GMR, or TMR.

15. The magnetic sensing apparatus of claim 1, wherein:
the magnetic conductive unit and the magnetic material layer of the inducing unit are formed by same magnetic material, and have same number of layers deposited in same step;
the magnetic conductive unit and the magnetic material layer of the inducing unit are formed by different magnetic material deposited in different steps.

16. A magnetic induction method using a magnetic sensing apparatus, comprising:
inducing magnetic field in a third direction;
collecting, by a magnetic conductive unit, magnetic signal in the third direction, and outputs the magnetic signal;
receiving, by an inducing unit, the magnetic signal in the third direction output by the magnetic conductive unit, and measure magnetic field strength and magnetic field direction corresponding to the third direction by the magnetic signal; and
directly offsetting, by each pair of magnetic sensing modules, the output magnetic field signal in first and second direction of the pair of magnetic sensing modules, after setup of each pair of magnetic sensing modules in the magnetic sensing apparatus is complete.

17. The magnetic induction method of claim 16, further comprising:
inducing in first direction and second direction, the magnetic signal in the first direction and second direction; and
measuring the magnetic field strength and magnetic field direction corresponding to the first direction and the second direction.
